(19) United States
(12) Patent Application Publication
(10) Pub. No.: US 2026/0058605 A1
(43) Pub. Date: Feb. 26, 2026

(54) DYNAMIC IMPEDANCE MODULATION IN A POWER MANAGEMENT CIRCUIT

(71) Applicant: Qorvo US, Inc., Greensboro, NC (US)

(72) Inventor: Nadim Khlat, Ceret (FR)

(21) Appl. No.: 19/274,857

(22) Filed: Jul. 21, 2025

Related U.S. Application Data
(60) Provisional application No. 63/684,919, filed on Aug. 20, 2024.

(51) Int. Cl. H03F 1/02; H03F 3/24; H04B 1/40

(52) U.S. Cl. CPC H03F 1/0211; H03F 3/245; H04B 1/40; H03F 2200/105; H03F 2200/451

(57) ABSTRACT

Dynamic impedance modulation in a power management circuit is provided. The power management circuit, which includes a power management integrated circuit (PMIC) and a power amplifier circuit, is configured to amplify a radio frequency (RF) signal for transmission. Herein, the PMIC is configured to generate a supply voltage in accordance with a time-variant power envelope of the RF signal and the power amplifier circuit is configured to amplify the RF signal based on the supply voltage. Specifically, an impedance modulation circuit is provided in the power amplifier circuit and configured according to various embodiments to perform a load modulation when an instantaneous power level of the RF signal falls within a defined power range. As a result, it is possible to reduce a dynamic voltage range (e.g., peak-to-peak voltage range) of the supply voltage to help improve efficiency of the power management circuit.

### RELATED APPLICATIONS

This application claims the benefit of U.S. provisional patent application Ser. No. 63/684,919, filed on Aug. 20, 2024, the disclosure of which is hereby incorporated herein by reference in its entirety.

### FIELD OF THE DISCLOSURE

The present disclosure is related to an impedance modulation circuit that can perform dynamic impedance modulation in a power management circuit.

### BACKGROUND

Mobile communication devices have become increasingly common in current society for providing wireless communication services. The prevalence of these mobile communication devices is driven in part by the many functions that are now enabled on such devices. Increased processing capabilities in such devices means that mobile communication devices have evolved from being pure communication tools into sophisticated mobile multimedia centers that enable enhanced user experiences.

The redefined user experience requires higher data rates offered by advanced wireless communication technologies such as fifth-generation new-radio (5G-NR). To achieve higher data rates, a mobile communication device is required to amplify a transmission signal to a desired power level to help overcome potential propagation losses and/or interferences. As such, the mobile communication device typically includes a transceiver circuit, a power amplifier circuit, and a power management circuit. Specifically, the transceiver circuit modulates the transmission signal to an intended transmission frequency, the power amplifier circuit amplifies the transmission signal to the desired power level, and the power management circuit supplies an envelope tracking (ET) voltage to the power amplifier circuit. Understandably, to achieve the best-possible efficiency and performance, the power management circuit must adapt the ET voltage in accordance with a modulation bandwidth of the transmission signal.

### SUMMARY

Embodiments of the disclosure relate to dynamic impedance modulation in a power management circuit. The power management circuit, which includes a power management integrated circuit (PMIC) and a power amplifier circuit, is configured to amplify a radio frequency (RF) signal for transmission. Herein, the PMIC is configured to generate a supply voltage in accordance with a time-variant power envelope of the RF signal and the power amplifier circuit is configured to amplify the RF signal based on the supply voltage. Specifically, an impedance modulation circuit is provided in the power amplifier circuit and configured according to various embodiments to perform a load modulation when an instantaneous power level of the RF signal falls within a defined power range (e.g., below a maximum power threshold and above a minimum power threshold). As a result, it is possible to reduce a dynamic voltage range (e.g., peak-to-peak voltage range) of the supply voltage to help improve efficiency of the power management circuit.

In one aspect, a power management circuit is provided. The power management circuit includes a power amplifier circuit. The power amplifier circuit includes a power amplifier. The power amplifier is configured to amplify an RF signal based on a supply voltage. The power amplifier circuit also includes an impedance modulation circuit. The impedance modulation circuit is coupled in series to the power amplifier. The impedance modulation circuit is configured to modulate a load impedance at an output of the power amplifier to thereby reduce a voltage range of the supply voltage. The power management circuit includes a PMIC. The PMIC is configured to generate and provide the supply voltage to the power amplifier. The PMIC is also configured to generate and provide a load modulation signal to the impedance modulation circuit to indicate a modulated load impedance when a power level of the RF signal is below a first power threshold and above a second power threshold lower than the first power threshold.

In another aspect, a wireless device is provided. The wireless device includes a transceiver circuit. The transceiver circuit is configured to generate an RF signal. The transceiver circuit is also configured to generate a target voltage modulated according to a time-variant power envelope of the RF signal. The wireless device also includes a power amplifier circuit. The power amplifier circuit includes a power amplifier. The power amplifier is configured to amplify the RF signal based on a supply voltage. The power amplifier circuit also includes an impedance modulation circuit. The impedance modulation circuit is coupled in series to the power amplifier. The impedance modulation circuit is configured to modulate a load impedance at the output of the power amplifier to thereby reduce a voltage range of the supply voltage. The wireless device also includes a PMIC. The PMIC is configured to generate a supply voltage based on the target voltage and provide the supply voltage to the power amplifier. The PMIC is also configured to generate and provide a load modulation signal to the impedance modulation circuit to indicate the modulated load impedance when a power level of the RF signal is below a first power threshold and above a second power threshold lower than the first power threshold.

In another aspect, a method for supporting dynamic impedance modulation in a power management circuit is provided. The method includes amplifying an RF signal based on a supply voltage. The method also includes modulating a load impedance to thereby reduce a voltage range of the supply voltage. The method also includes generating a load modulation signal indicating the load impedance when a power level of the RF signal is below a first power threshold and above a second power threshold lower than the first power threshold.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1 is a schematic diagram of an exemplary power management circuit wherein an impedance modulation circuit can be provided in a power amplifier circuit and configured according to various embodiments to support load modulation based on an instantaneous power level of a radio frequency (RF) signal being amplified by the power amplifier circuit;

FIG. 2 is a graphic diagram providing an exemplary illustration as to how the power management circuit of FIG. 1 can operate based on a combination of load modulation and supply modulation across a wide power range of the RF signal;

FIG. 3 is a schematic diagram of the impedance modulation circuit in FIG. 1 wherein a control circuit can control a modulated impedance inverter to support load modulation;

FIG. 4 is a schematic diagram of an exemplary equivalent electrical model that helps explain configuration requirements for the modulated impedance inverter in FIG. 3;

FIGS. 5A and 5B are schematic diagrams illustrating various embodiments of the control circuit in FIG. 3;

FIGS. 6A-6G are schematic diagrams illustrating various embodiments of the modulated impedance inverter in FIG. 3;

FIG. 7 is a schematic diagram of an exemplary communication device wherein the power management circuit of FIG. 1 can be provided; and

FIG. 8 is a flowchart of an exemplary process for supporting dynamic impedance modulation in the power management circuit of FIG. 1.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to dynamic impedance modulation in a power management circuit. The power management circuit, which includes a power management integrated circuit (PMIC) and a power amplifier circuit, is configured to amplify a radio frequency (RF) signal for transmission. Herein, the PMIC is configured to generate a supply voltage in accordance with a time-variant power envelope of the RF signal and the power amplifier circuit is configured to amplify the RF signal based on the supply voltage. Specifically, an impedance modulation circuit is provided in the power amplifier circuit and configured according to various embodiments to perform a load modulation when an instantaneous power level of the RF signal falls within a defined power range (e.g., below a maximum power threshold and above a minimum power threshold). As a result, it is possible to reduce a dynamic voltage range (e.g., peak-to-peak voltage range) of the supply voltage to help improve efficiency of the power management circuit.

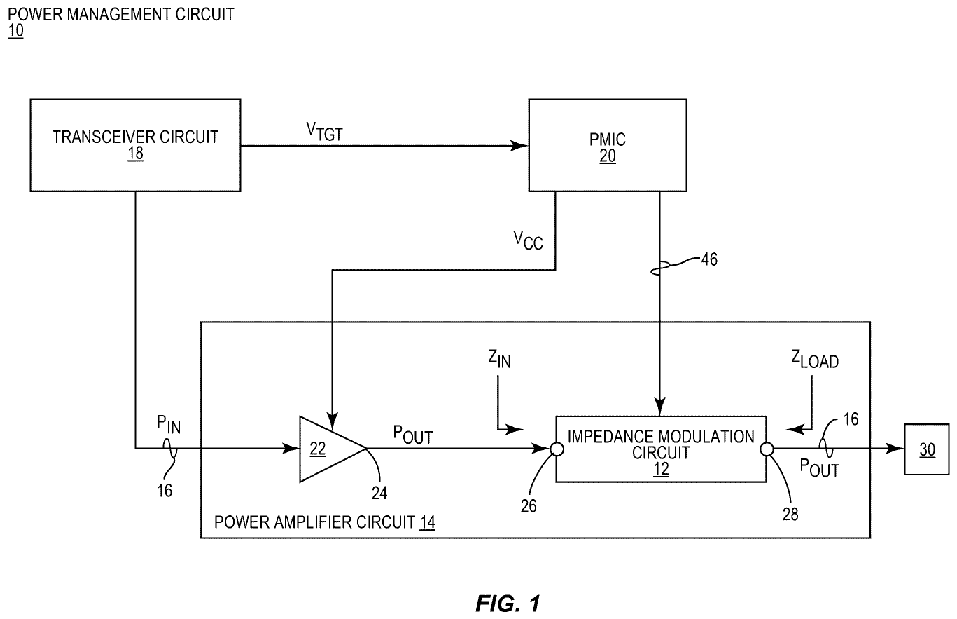

FIG. 1 is a schematic diagram of an exemplary power management circuit 10 wherein an impedance modulation circuit 12 can be provided in a power amplifier circuit 14 and configured according to various embodiments to support load modulation based on an instantaneous power level of an RF signal 16 being amplified by the power amplifier circuit 14. The power management circuit 10 also includes a transceiver circuit 18 and a PMIC 20. The transceiver circuit 18 is configured to generate the RF signal 16 associated with a time-variant power envelope and a target voltage V_{TGT} modulated according to the time-variant power envelope of the RF signal 16.

The PMIC 20 is configured to generate a supply voltage V_{CC} based on the target voltage V_{TGT}. In one embodiment, the supply voltage V_{CC} can be an envelope tracking (ET) voltage (a.k.a. modulated voltage) that is modulated to track the time-variant power envelope of the RF signal 16. In another embodiment, the supply voltage V_{CC} can be an average power tracking (APT) voltage (a.k.a. non-modulated voltage) that is generated in accordance with an average of the time-variant power envelope of the RF signal 16.

In an embodiment, the power amplifier circuit 14 includes a power amplifier 22 that is coupled in series to the impedance modulation circuit 12. Specifically, an output 24 of the power amplifier 22 is coupled to an input node 26 of the impedance modulation circuit 12 and an output node 28 of the impedance modulation circuit 12 is coupled to a load circuit 30 (e.g., an RF frontend circuit). The power amplifier 22 receives the RF signal 16 from the transceiver circuit 18 and amplifies the RF signal 16 from a time-variant input power P_{IN} to a time-variant output power P_{OUT} based on the supply voltage V_{CC} provided by the PMIC 20. The impedance modulation circuit 12, on the other hand, is configured to present a modulated load impedance Z_{IN} at the output 24 of the power amplifier 22 in accordance with the instantaneous power level of the RF signal 16. Herein, the modulated load impedance Z_{IN} is a function of a load impedance Z_{LOAD} seen at the output node 28 of the impedance modulation circuit 12, which can be expressed in equation (Eq. 1) below.

$${Z}_{IN} = - {K}^{2} / {Z}_{LOAD} \qquad ( Eq . 1 )$$

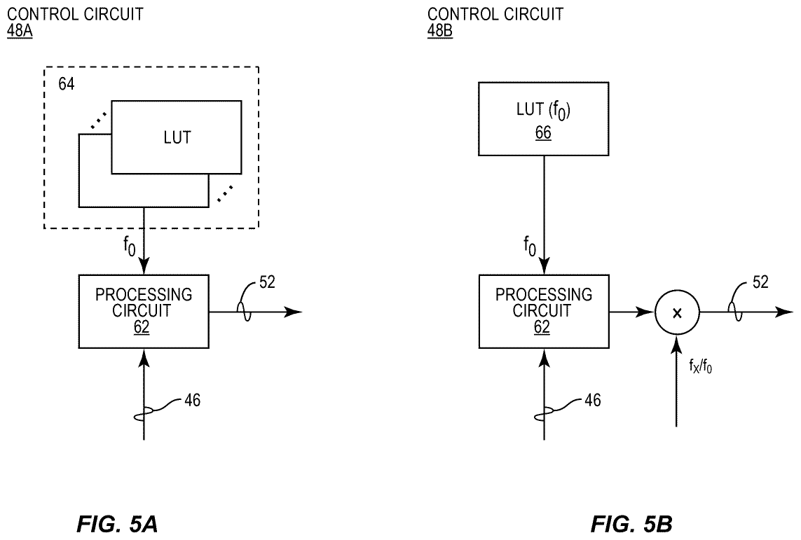

In the equation (Eq. 1), K represents a configurable modulation term of the impedance modulation circuit 12. As further described below in FIGS. 5A-5G, for a given load impedance Z_{LOAD}, the impedance modulation circuit 12 can be configured to present a different modulated load impedance Z_{IN} by manipulating the configurable modulation term K.

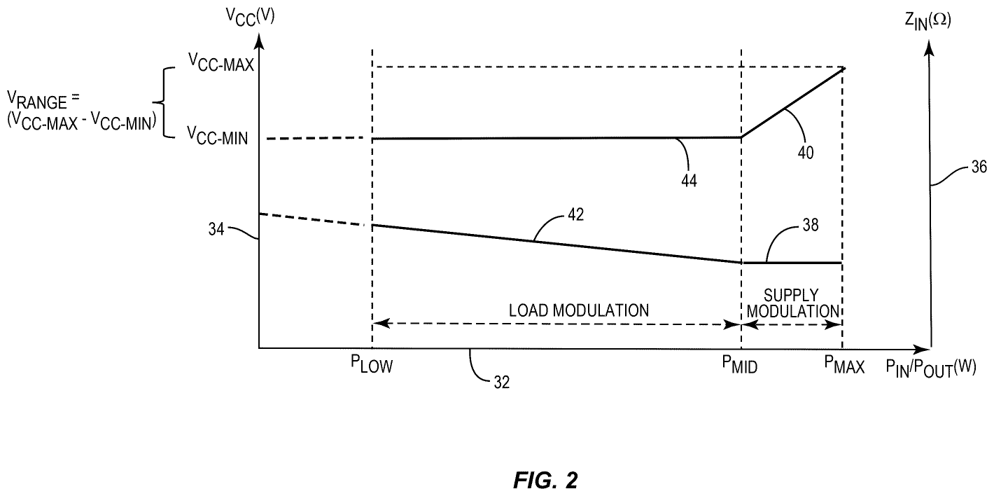

In an embodiment, the power management circuit 10 is configured to amplify the RF signal 16 based on a combination of load modulation and supply modulation. More specifically, the power management circuit 10 is configured to perform load modulation and/or supply modulation based on the time-variant input power P_{IN} and/or the time-variant output power P_{OUT} of the RF signal 16. FIG. 2 is a graphic diagram providing an exemplary illustration as to how the power management circuit 10 of FIG. 1 can operate based on a combination of the load modulation and the supply modulation across a wide power range of the RF signal 16. Common elements between FIGS. 1 and 2 are shown therein with common element numbers and will not be re-described herein.

Herein, the time-variant input power P_{IN} and/or the time-variant output power P_{OUT} is represented by a horizontal axis 32, the supply voltage V_{CC} is represented by a first vertical axis 34, and the modulated load impedance Z_{IN} is represented by a second vertical axis 36.

The power management circuit 10 can be configured with multiple power thresholds P_{MAX}, P_{MID}, and P_{LOW}. Herein, P_{MAX} represents a peak power threshold, P_{MID} represents a medium power threshold below the peak power threshold P_{MAX}, and P_{LOW} represents a lower power threshold below the medium power threshold P_{MID} (P_{LOW}<P_{MID}<P_{MAX}). In an embodiment, the medium power threshold P_{MID} can be 6 dB below the maximum power threshold P_{MAX} (P_{MID}=P_{MAX}−6 dB).

When the instantaneous power of the RF signal 16 is higher than or equal to the medium power threshold P_{MID} (e.g., P_{IN}/P_{OUT}≥P_{MID}), the power management circuit 10 is configured to operate based on the supply modulation. Accordingly, the power management circuit 10 will maintain the modulated load impedance Z_{IN} (as illustrated by line 38) and increase the supply voltage V_{CC} (as illustrated by line 40) towards a maximum supply voltage V_{CC-MAX}.

In contrast, when the instantaneous power of the RF signal 16 is below the medium power threshold P_{MID} and above the lower power threshold P_{LOW} (e.g., P_{LOW}<P_{IN}/P_{OUT}<P_{MID}), the power management circuit 10 is configured to operate based on the load modulation. Accordingly, the power management circuit 10 will reduce the modulated load impedance Z_{IN} (as illustrated by line 42) and maintain the supply voltage V_{CC} (as illustrated by line 44) at a minimum supply voltage V_{CC-MIN}. Alternatively, the power management circuit 10 may also operate based on a combination of the load modulation and the supply modulation. In this regard, the power management circuit 10 may slightly increase the supply voltage V_{CC} by performing both the load modulation and the supply modulation. By applying the combination of the load modulation and the supply modulation based on the power threshold P_{MID}, it is possible to raise the minimum supply voltage V_{CC-MIN}. As a result, a voltage range V_{RANGE} of the supply voltage V_{CC}, as defined by the maximum supply V_{CC-MAX} and the minimum supply V_{CC-MIN}, can be reduced to help improve operating efficiency of the PMIC and the power management circuit 10 as a whole.

When the instantaneous power of the RF signal 16 is below the lower power threshold P_{LOW} (e.g., P_{IN}/P_{OUT} P_{LOW}), the impedance modulation circuit 12 may be configured to present the modulated load impedance Z_{IN} to be more than four times the load impedance Z_{LOAD} (Z_{IN}>4*Z_{LOAD}). As an example, the configurable modulation term K can be determined by a ratio of the medium power threshold P_{MID} and the lower power threshold P_{LOW} (e.g., K=P_{MID}/P_{LOW}).

In context of the present disclosure, the primary focus is how to configure and control the impedance modulation circuit 12 to dynamically adapt the modulated load impedance Z_{IN} when the instantaneous power level of the RF signal 16 is below the medium power threshold P_{MID} (a.k.a. “first power threshold”) and above the lower power threshold P_{LOW} (a.k.a. “second power threshold”). In this regard, with reference back to FIG. 1, the PMIC 20 can be configured to determine and provide a load modulation signal 46 to the impedance modulation circuit 12. The load modulation signal 46 can be configured to indicate an expected value (or range) of the modulated load impedance Z_{IN} when the instantaneous power level of the RF signal 16 is below the first power threshold P_{MID} and above the second power threshold P_{LOW} (e.g., P_{LOW}<P_{IN}/P_{OUT}<P_{MID}). The impedance modulation circuit 12 can thus present the modulated load impedance Z_{IN} at the output 24 of the power amplifier 22 in accordance with the load modulation signal 46.

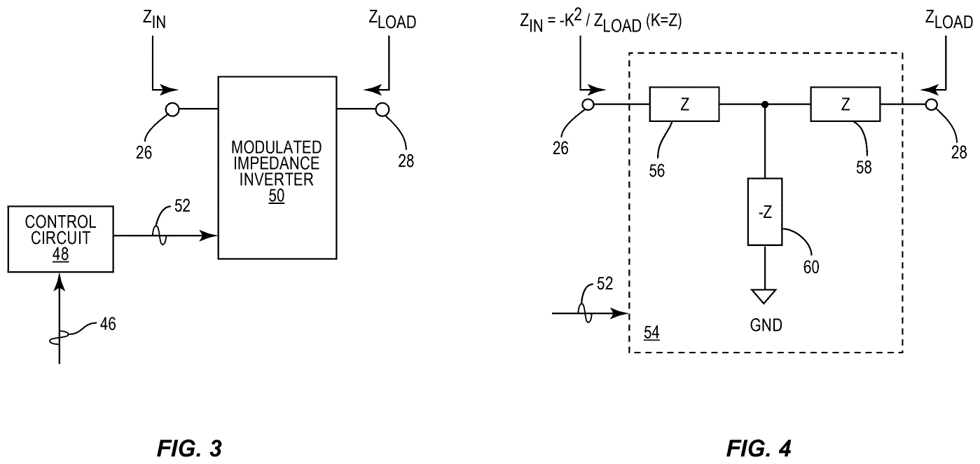

FIG. 3 is a schematic diagram of the impedance modulation circuit 12 in FIG. 1 wherein a control circuit 48 can control a modulated impedance inverter 50 to perform the load modulation in the power management circuit 10. Common elements between FIGS. 1 and 3 are shown therein with common element numbers and will not be re-described herein.

The control circuit 48 is configured to receive the load modulation signal 46. Accordingly, the control circuit 48 can determine at least one configuration parameter 52 based on the modulated load impedance Z_{IN} indicated by the load modulation signal 46. The modulated impedance inverter 50, which is coupled between the input node 26 and the output node 28, will then modulate and present the modulated load impedance Z_{IN} based on the configuration parameter 52 provided by the control circuit 48.

Being configured to operate as a passive impedance inverter, the modulated impedance inverter 50 must be configured to satisfy some specific configuration requirements. FIG. 4 is a schematic diagram of an exemplary equivalent electrical model 53 that helps explain the configuration requirements for the modulated impedance inverter 50 in FIG. 3. Common elements between FIGS. 3 and 4 are shown therein with common element numbers and will not be re-described herein.

Herein, the modulated impedance inverter 50 in FIG. 3 can be modeled by an equivalent T-network 54, which includes a pair of series elements 56, 58 and a shunt element 60 configured as illustrated. Herein, the configurable modulation term K can be determined by an impedance term Z of each of the series elements 56, 58 (K=Z). Accordingly, the modulated load impedance Z_{IN} can be expressed in equation (Eq. 2) below.

$${Z}_{IN} = - {K}^{2} / {Z}_{LOAD} = - {Z}^{2} / {Z}_{LOAD} \qquad ( Eq . 2 )$$

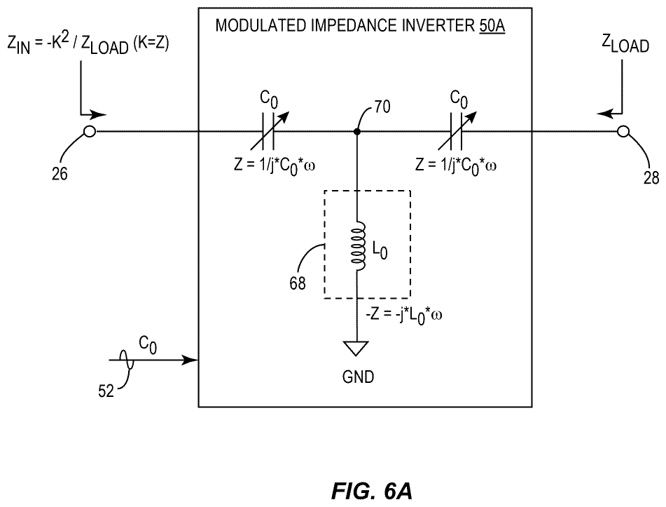

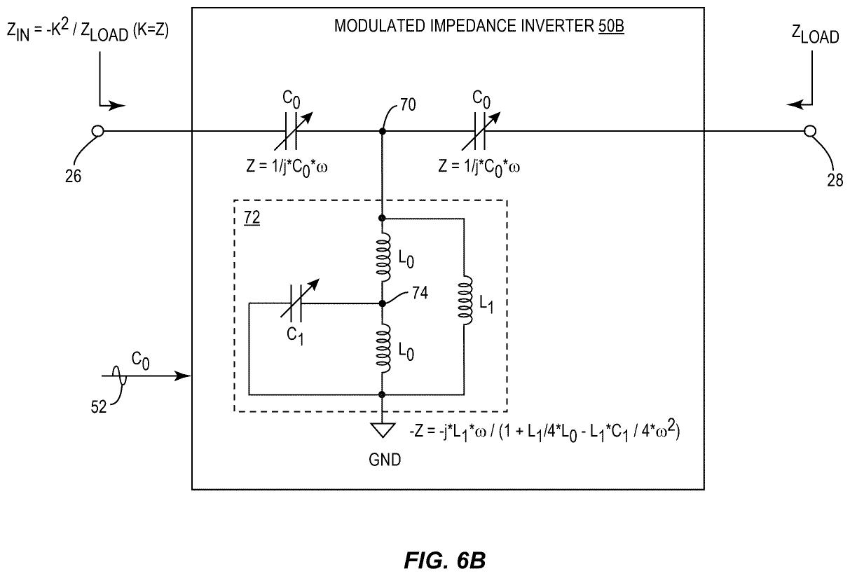

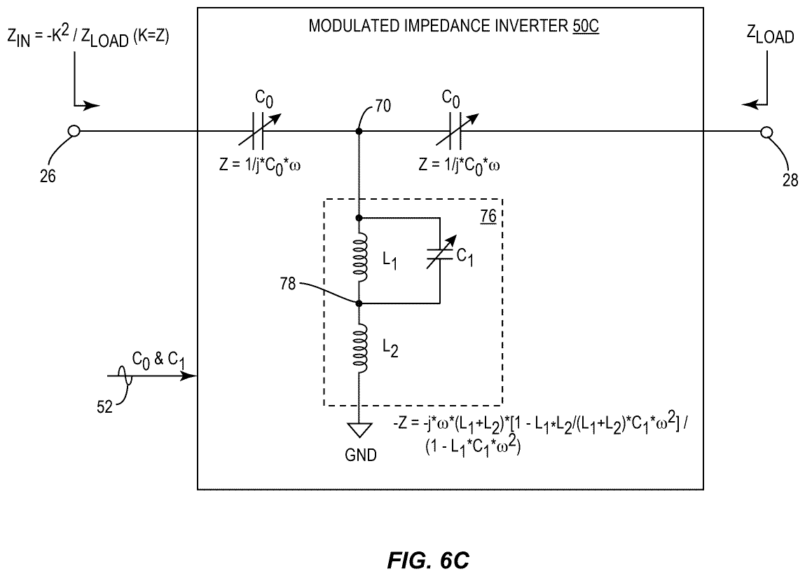

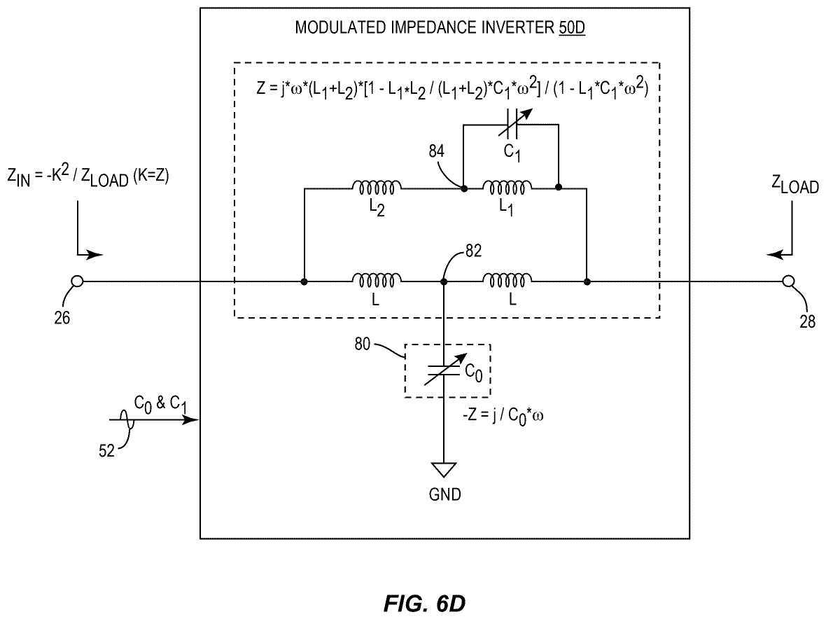

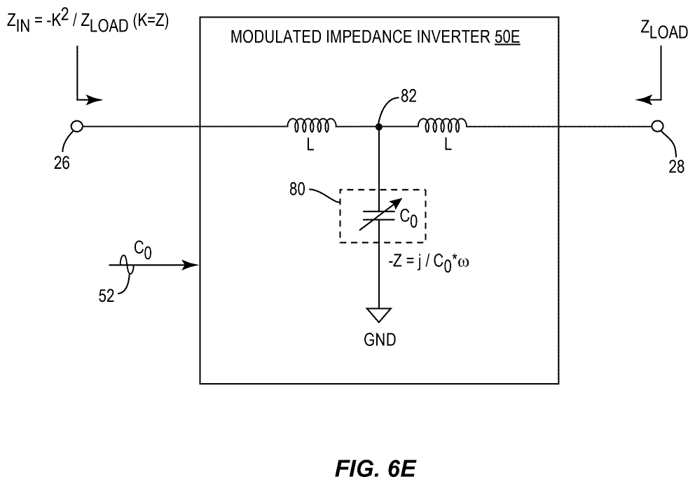

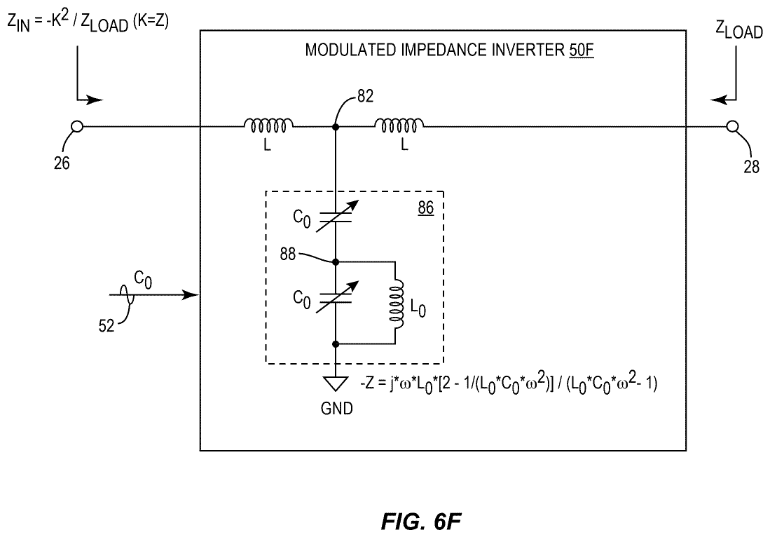

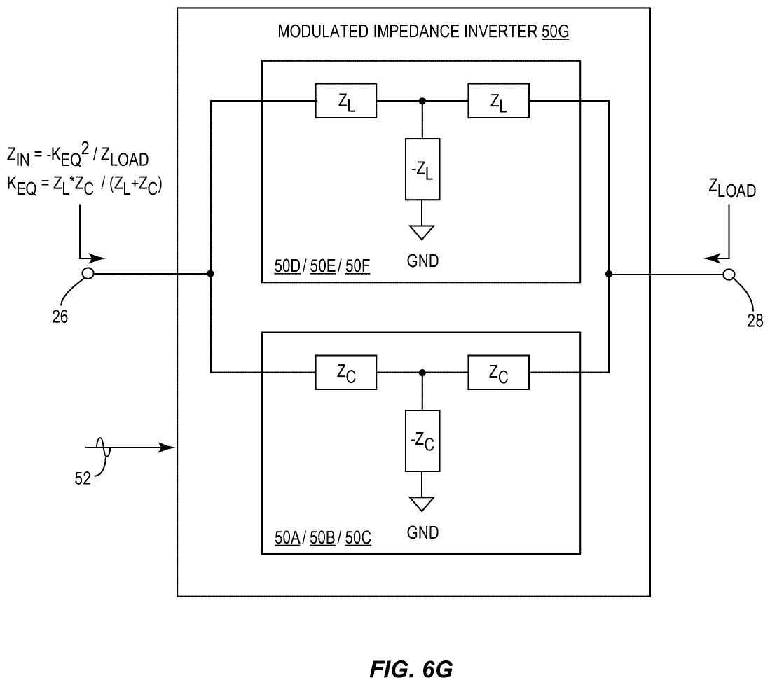

In addition, to operate as the passive impedance inverter, the shunt element 60 must be configured to present a shunt impedance term −Z. In this regard, the configuration requirements for the impedance modulation circuit 12 are to determine the impedance term Z to thereby present the desired modulated load impedance Z_{IN} as well as the shunt impedance term −Z such that the modulated impedance inverter 50 can operate as the passive impedance inverter. As further described in FIGS. 6A-6G, the impedance term Z and/or the shunt impedance term −Z can be determined based on the configuration parameter 52 that is provided by the control circuit 48.

The control circuit 48 can be configured to determine the configuration parameter 52 according to various embodiments of the present disclosure, as described next in FIGS. 5A and 5B. Common elements between FIGS. 3, 5A, and 5B are shown therein with common element numbers and will not be re-described herein.

FIG. 5A is a schematic diagram illustrating a control circuit 48A configured according to one embodiment of the present disclosure and can function as the control circuit 48 in FIG. 3. Herein, the control circuit 48A includes a processing circuit 62 and multiple lookup tables (LUTs) 64. Each of the LUTs 64 can be configured to the modulated load impedance Z_{IN} with one or more respective configuration parameters at a respective modulation center frequency. The processing circuit 62 receives the load modulation signal 46 indicating the modulated load impedance Z_{IN} at a specific modulation center frequency f₀. Accordingly, the processing circuit 62 retrieves the configuration parameter 52 from one of the LUTs 64 that corresponds to the specific modulation center frequency f₀ to thereby generate the configuration parameter 52.

FIG. 5B is a schematic diagram illustrating a control circuit 48B configured according to another embodiment of the present disclosure and can function as the control circuit 48 in FIG. 3. Herein, the control circuit 48B includes a LUT 66 configured to correlate the modulated load impedance Z_{IN} with one or more configuration parameters at a predefined modulation center frequency (e.g., f₀). The processing circuit 62 receives the load modulation signal 46 indicating the modulated load impedance Z_{IN} at a selected modulation center frequency (e.g., f_{X}). Accordingly, the processing circuit 62 selects the configuration parameters from the LUT 66, which corresponds to the predefined modulation center frequency f₀. Subsequently, the processing circuit 62 scales the selected configuration parameter from the predefined modulation center frequency f₀ to the selected modulation center frequency f_{X} (e.g., f_{X}/f₀) to thereby generate the configuration parameter 52.

FIGS. 6A-6G are schematic diagrams illustrating various embodiments of the modulated impedance inverter 50 in FIG. 3. Common elements between FIGS. 3 and 6A-6G are shown therein with common element numbers and will not be re-described herein.

FIG. 6A illustrates a modulated impedance inverter 50A configured according to one embodiment of the present disclosure to operate as the modulated impedance inverter 50 in FIG. 3. Herein, the modulated impedance inverter 50A includes a pair of tunable capacitors C₀ and a shunt element 68. The pair of tunable capacitors C₀, each of which has a respective capacitance C₀, are coupled in series between the input node 26 and the output node 28. In this embodiment, the shunt element 68 includes an inductor L₀. The inductor L₀ has a respective inductance L₀ and is coupled between a middle node 70 located between the tunable capacitors C₀ and a ground (GND). The control circuit 48 in FIG. 3 is configured to provide the configuration parameter 52 that indicates the respective capacitance C₀ of each of the tunable capacitors C₀ to thereby cause the modulated impedance inverter 50A to provide the modulated load impedance Z_{IN} based on the equation (Eq. 1) above. Specifically, the impedance term Z and the shunt impedance term −Z can be expressed as in equation (Eq. 3) below. Herein, w represents a modulated frequency of the RF signal 16.

$$Z = 1 / j * {C}_{0} * ω \qquad ( Eq . 3 )$$

$$- Z = - j * {L}_{0} * ω$$

FIG. 6B illustrates a modulated impedance inverter 50B configured according to another embodiment of the present disclosure to operate as the modulated impedance inverter 50 in FIG. 3. Herein, the modulated impedance inverter 50B includes a pair of tunable capacitors C₀ and a shunt element 72. The tunable capacitors C₀, each of which has a respective capacitance C₀, are coupled in series between the input node 26 and the output node 28.

In this embodiment, the shunt element 72 includes a pair of inductors L₀, a second inductor L₁, and a second tunable capacitor C₁. The pair of inductors L₀ are coupled in series between the middle node 70 and the GND, the second inductor L₁ is also coupled between the middle node 70 and the GND in parallel to the pair of inductors L₀, whereas the second tunable capacitor C₁ is coupled between a middle node 74, which is located between the pair of inductors L₀, and the GND.

The control circuit 48 in FIG. 3 is configured to provide the configuration parameter 52 that indicates the capacitance C₀ of each of the pair of tunable capacitors C₀ and/or the capacitance C₁ of the second tunable capacitor C₁ to thereby cause the modulated impedance inverter 50B to provide the modulate load impedance Z_{IN} based on the equation (Eq. 1) above. Specifically, the impedance term Z and the shunt impedance term −Z can be expressed as in equation (Eq. 4) below.

$$Z = 1 / j * {C}_{0} * ω \qquad ( Eq . 4 )$$

$$- Z = - j * {L}_{1} * ω / ( 1 + {L}_{1} / 4 * {L}_{0} - {L}_{1} * {C}_{1} / 4 * {ω}^{2} )$$

FIG. 6C illustrates a modulated impedance inverter 50C configured according to another embodiment of the present disclosure to operate as the modulated impedance inverter 50 in FIG. 3. Herein, the modulated impedance inverter 50C includes a pair of tunable capacitors C₀ and a shunt element 76. The tunable capacitors C₀, each of which has a respective capacitance C₀, are coupled in series between the input node 26 and the output node 28.

In this embodiment, the shunt element 76 includes a pair of inductors L₁, L₂ and a second tunable capacitor C₁ that has a capacitance of C₁. The inductors L₁, L₂ are coupled in series between the middle node 70 located between the pair of tunable capacitors C₀ and the GND. The second tunable capacitor C₁ is coupled between the middle node 70 located between the pair of tunable capacitors C₀ and a middle node 78 located between the inductors L₁, L₂.

The control circuit 48 in FIG. 3 is configured to provide the configuration parameter 52 that indicates the capacitance C₀ of each of the pair of tunable capacitors C₀ and/or the capacitance C₁ of the second tunable capacitor C₁ to thereby cause the modulated impedance inverter 50C to provide the modulated load impedance Z_{IN} based on the equation (Eq. 1) above. Specifically, the impedance term Z and the shunt impedance term −Z can be expressed as in equation (Eq. 5) below.

$$Z = 1 / j * {C}_{0} * ω \qquad ( Eq . 5 )$$

$$- Z = - j * ω * ( {L}_{1} + {L}_{2} ) * [ 1 - {L}_{1} * {L}_{2} / ( {L}_{1} + {L}_{2} ) * {C}_{1} * {ω}^{2} ] / ( 1 - {L}_{1} * {C}_{1} * {ω}^{2} )$$

FIG. 6D illustrates a modulated impedance inverter 50D configured according to another embodiment of the present disclosure to operate as the modulated impedance inverter 50 in FIG. 3. Herein, the modulated impedance inverter 50D includes a pair of first inductors L, a pair of second inductors L₁, L₂, a tunable capacitor C₀, and a second tunable capacitor C₁.

In this embodiment, the first inductors L are coupled in series between the input node 26 and the output node 28. The pair of second inductors L₁, L₂ are also coupled in series between the input node 26 and the output node 28 in parallel to the pair of first inductors L. The tunable capacitor C₀, which forms a shunt element 80, is coupled between a middle node 82 located between the pair of first inductors L and the GND ground. The second tunable capacitor C₁ is coupled between a middle node 84 located between the pair of second inductors L₁, L₂ and the output node 28.

The control circuit 48 in FIG. 3 is configured to provide the configuration parameter 52 that indicates the capacitance C₀ of the tunable capacitors C₀ and/or the capacitance C₁ of the second tunable capacitor C₁ to thereby cause the modulated impedance inverter 50D to provide the modulated load impedance Z_{IN} based on the equation (Eq. 1) above. Specifically, the impedance term Z and the shunt impedance term −Z can be expressed as in equation (Eq. 6) below.

$$Z = j * ω * [ {L}_{1} + {L}_{2} ) * ( 1 - {L}_{1} * {L}_{2} / ( {L}_{1} + {L}_{2} ) * {C}_{1} * {ω}^{2} ] / ( 1 - {L}_{1} * {C}_{1} * {ω}^{2} ) \qquad ( Eq . 6 )$$

$$- Z = j / {C}_{0} * ω$$

FIG. 6E illustrates a modulated impedance inverter 50E configured according to another embodiment of the present disclosure to operate as the modulated impedance inverter 50 in FIG. 3. Herein, the modulated impedance inverter 50E includes a pair of inductors L and a tunable capacitor C₀.

In this embodiment, the pair of inductors L are coupled in series between the input node 26 and the output node 28. The tunable capacitor C₀, which forms the shunt element 80, is coupled between the middle node 82 located between the pair of inductors L and the ground GND.

The control circuit 48 in FIG. 3 is configured to provide the configuration parameter 52 that indicates the capacitance C₀ of the tunable capacitors C₀ to thereby cause the modulated impedance inverter 50E to provide the modulate load impedance Z_{IN} based on the equation (Eq. 1) above. Specifically, the shunt impedance term −Z can be expressed as in equation (Eq. 7) below.

$$- Z = j / {C}_{0} * ω \qquad ( Eq . 7 )$$

FIG. 6F illustrates a modulated impedance inverter 50F configured according to another embodiment of the present disclosure to operate as the modulated impedance inverter 50 in FIG. 3. Herein, the modulated impedance inverter 50F includes a pair of inductors L and a shunt element 86.

In this embodiment, the inductors L are coupled in series between the input node 26 and the output node 28. The shunt element 86 includes a pair of tunable capacitors C₀ and a second inductor L₀. Specifically, the tunable capacitors C₀ are coupled in series between the middle node 82 located between the pair of inductors L and the ground GND, whereas the second inductor L₀ is coupled between a middle node 88 located between the pair of tunable capacitors C₀ and the ground GND.

The control circuit 48 in FIG. 3 is configured to provide the configuration parameter 52 that indicates the capacitance C₀ of the tunable capacitors C₀ to thereby cause the modulated impedance inverter 50F to provide the modulate load impedance Z_{IN} based on the equation (Eq. 1) above. Specifically, the shunt impedance term −Z can be expressed as in equation (Eq. 8) below.

$$- Z = j * ω * {L}_{0} * [ 2 - 1 / ( {L}_{0} * {C}_{0} * {ω}^{2} ) ] / ( {L}_{0} * {C}_{0} * {ω}^{2} - 1 ) \qquad ( Eq . 8 )$$

In an embodiment, it is also possible to configure a modulated impedance inverter based on a combination of any of the modulated impedance inverter 50A of FIG. 6A, the modulated impedance inverter 50B of FIG. 6B, the modulated impedance inverter 50C of FIG. 6C, the modulated impedance inverter 50D of FIG. 6D, the modulated impedance inverter 50E of FIG. 6E, and the modulated impedance inverter 50F of FIG. 6F. In this regard, FIG. 6G illustrates a modulated impedance inverter 50G configured according to another embodiment of the present disclosure to operate as the modulated impedance inverter 50 in FIG. 3.

In this embodiment, the modulated impedance inverter 50G may include a combination of any one of the modulated impedance inverter 50A of FIG. 6A, the modulated impedance inverter 50B of FIG. 6B, the modulated impedance inverter 50C of FIG. 6C and any one of the modulated impedance inverter 50D of FIG. 6D, the modulated impedance inverter 50E of FIG. 6E, and the modulated impedance inverter 50F of FIG. 6F.

Depending on the exact configuration of the modulated impedance inverter 50G, the control circuit 48 in FIG. 3 is configured to provide the configuration parameter 52 as appropriate as described above in FIGS. 6A-6F to thereby cause the modulated impedance inverter 50G to provide the modulated load impedance Z_{IN} based on the equation (Eq. 1) above. In a non-limiting example, the modulated impedance inverter 50G can present the modulated load impedance Z_{IN} as expressed in equation (Eq. 9) below.

$${Z}_{IN} = - {K}_{EQ}^{2} / {Z}_{LOAD} \qquad ( Eq . 9 )$$

$${K}_{EQ} = {Z}_{L} * {Z}_{C} / ( {Z}_{L} + {Z}_{C} )$$

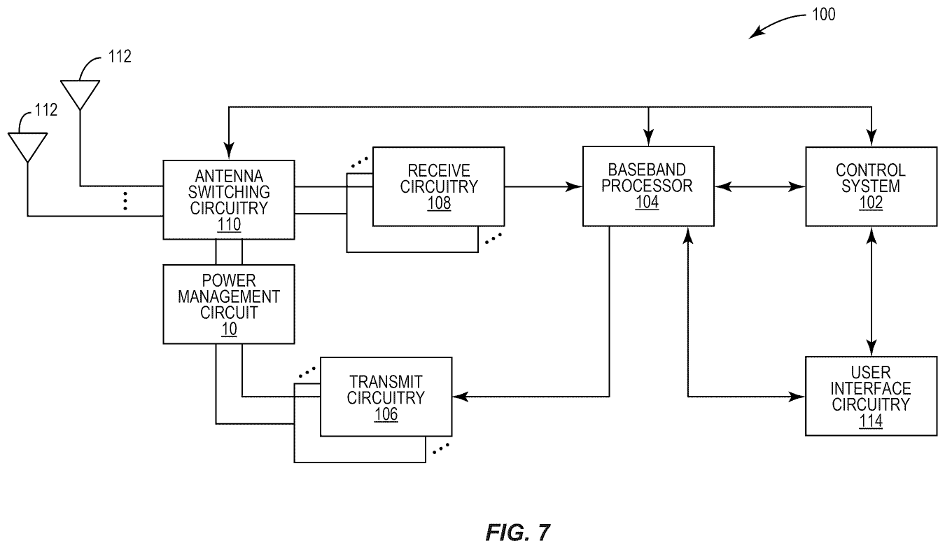

The power management circuit 10 of FIG. 1 can be provided in a communication device to support the embodiments described above. In this regard, FIG. 7 is a schematic diagram of an exemplary communication device 100 wherein the power management circuit 10 of FIG. 1 can be provided.

Herein, the communication device 100 can be any type of communication devices, such as mobile terminals, smart watches, tablets, computers, navigation devices, access points, base stations (e.g., eNB, gNB, etc.), and like wireless communication devices that support wireless communications, such as cellular, wireless local area network (WLAN), Ultra-wideband (UWB), Bluetooth, and near-field communications. The communication device 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor, an embedded memory circuit, and a communication bus interface. The receive circuitry 108 receives radio frequency signals via the antennas 112 and through the antenna switching circuitry 110 from one or more base stations. A low-noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converters (ADCs).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application-specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 112 through the antenna switching circuitry 110. The multiple antennas 112 and the replicated transmit 106 and receive circuitry 108 may provide spatial diversity. Modulation and processing details will be understood by those skilled in the art.

In an embodiment, the transmit circuitry 106 and the receive circuitry 108 can collectively function as the transceiver circuit 18 in FIG. 1. Accordingly, the power management circuit 10 can be provided between the transmit circuitry 106 and the antenna switching circuitry 110.

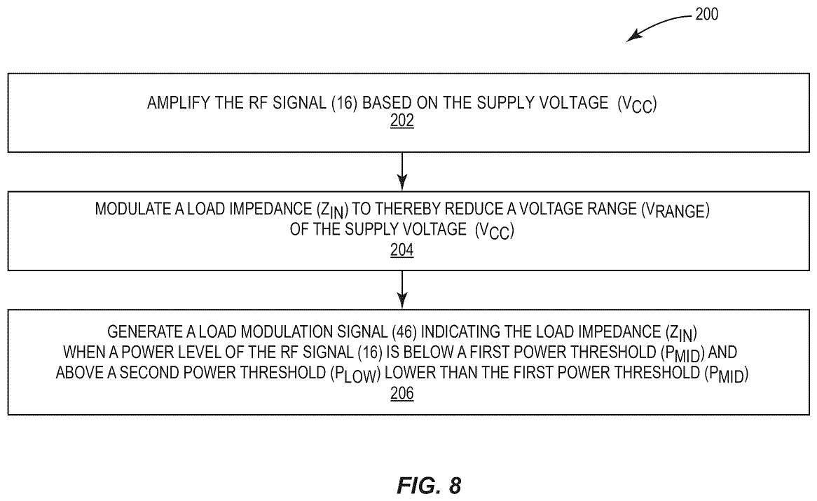

In an embodiment, the power management circuit 10 of FIG. 1 can be configured to support dynamic impedance modulation in accordance with a process. In this regard, FIG. 8 is a flowchart of an exemplary process 200 for supporting dynamic impedance modulation in the power management circuit 10 of FIG. 1.

Herein, the process 200 includes amplifying the RF signal 16 based on the supply voltage V_{CC} (step 202). The process 200 also includes modulating the load impedance Z_{IN} to thereby reduce the voltage range V_{RANGE} of the supply voltage V_{CC} (step 204). The process 200 also includes generating the load modulation signal 46 indicating the load impedance Z_{IN} when the power level of the RF signal 16 is below the first power threshold P_{MID} and above the second power threshold P_{LOW} lower than the first power threshold P_{MID} (step 206).

Those skilled in the art will recognize improvements and modifications to the preferred embodiments of the present disclosure. All such improvements and modifications are considered within the scope of the concepts disclosed herein and the claims that follow.

What is claimed is:

1. A power management circuit comprising:
a power amplifier circuit comprising:
a power amplifier configured to amplify a radio frequency (RF) signal based on a supply voltage; and
an impedance modulation circuit coupled in series with the power amplifier and configured to modulate a load impedance at an output of the power amplifier to thereby reduce a voltage range of the supply voltage; and
a power management integrated circuit (PMIC) configured to:
generate and provide the supply voltage to the power amplifier; and
generate and provide a load modulation signal to the impedance modulation circuit to indicate the load impedance at the output of the power amplifier when a power level of the RF signal is below a first power threshold and above a second power threshold lower than the first power threshold.

2. The power management circuit of claim 1, wherein the PMIC is further configured to generate the supply voltage as one of:
an envelope tracking (ET) voltage modulated in accordance with a time-variant power envelope of the RF signal; and
an average power tracking (APT) voltage tracking an average of the time-variant power envelope of the RF signal.

3. The power management circuit of claim 1, wherein the impedance modulation circuit comprises:
a modulated impedance inverter configured by at least one configuration parameter to modulate the load impedance at the output of the power amplifier; and
a control circuit configured to receive the load modulation signal and determine the at least one configuration parameter based on the load impedance indicated by the load modulation signal.

4. The power management circuit of claim 3, wherein the control circuit comprises:
a plurality of lookup tables (LUTs) configured to correlate the load impedance with the at least one configuration parameter at a plurality of modulation center frequencies, respectively; and
a processing circuit configured to:
receive the load modulation signal indicating the load impedance at a respective one of the plurality of modulation center frequencies; and
determine the at least one configuration parameter from a respective one of the plurality of LUTs.

5. The power management circuit of claim 3, wherein the control circuit comprises:
a lookup table (LUT) configured to correlate the load impedance with the at least one configuration parameter at a predefined modulation center frequency; and
a processing circuit configured to:
receive the load modulation signal indicating the load impedance at a selected modulation center frequency;
select the at least one configuration parameter from the LUT; and
scale the at least one configuration parameter from the predefined modulation center frequency to the selected modulation center frequency.

6. The power management circuit of claim 3, wherein the modulated impedance inverter comprises:
a pair of tunable capacitors coupled in series between an input node and an output node; and
an inductor coupled between a respective middle node located between the pair of tunable capacitors and a ground;
wherein the at least one configuration parameter comprises a respective capacitance of each of the pair of tunable capacitors.

7. The power management circuit of claim 3, wherein the modulated impedance inverter comprises:
a pair of tunable capacitors coupled in series between an input node and an output node;
a pair of inductors coupled in series between a respective middle node located between the pair of tunable capacitors and a ground;
a second inductor coupled between the middle node and the ground in parallel to the pair of inductors; and
a second tunable capacitor coupled between a respective middle node located between the pair of inductors and the ground;
wherein the at least one configuration parameter comprises one or more of:
a respective capacitance of each of the pair of tunable capacitors; and
a respective capacitance of the second tunable capacitor.

8. The power management circuit of claim 3, wherein the modulated impedance inverter comprises:
a pair of tunable capacitors coupled in series between an input node and an output node;
a pair of inductors coupled in series between a respective middle node located between the pair of tunable capacitors and a ground; and
a second tunable capacitor coupled between the respective middle node located between the pair of tunable capacitors and a respective middle node located between the pair of inductors;
wherein the at least one configuration parameter comprises one or more of:
a respective capacitance of each of the pair of tunable capacitors; and
a respective capacitance of the second tunable capacitor.

9. The power management circuit of claim 3, wherein the modulated impedance inverter comprises:
a pair of first inductors coupled in series between an input node and an output node;
a pair of second inductors coupled in series between the input node and the output node in parallel to the pair of first inductors;
a tunable capacitor coupled between a respective middle node located between the pair of first inductors and a ground; and
a second tunable capacitor coupled between a respective middle node located between the pair of second inductors and the output node;
wherein the at least one configuration parameter comprises one or more of:
a respective capacitance of the tunable capacitor; and
a respective capacitance of the second tunable capacitor.

10. The power management circuit of claim 3, wherein the modulated impedance inverter comprises:
a pair of inductors coupled in series between an input node and an output node; and
a tunable capacitor coupled between a respective middle node located between the pair of inductors and a ground;
wherein the at least one configuration parameter comprises a respective capacitance of the tunable capacitor.

11. The power management circuit of claim 3, wherein the modulated impedance inverter comprises:
a pair of inductors coupled in series between an input node and an output node;
a pair of tunable capacitors coupled in series between a respective middle node located between the pair of inductors and a ground; and
a second inductor coupled between a respective middle node located between the pair of tunable capacitors and the ground;
wherein the at least one configuration parameter comprises a respective capacitance of each of the pair of tunable capacitors.

12. A wireless device comprising:
a transceiver circuit configured to generate a radio frequency (RF) signal and a target voltage modulated according to a time-variant power envelope of the RF signal;
a power amplifier circuit comprising:
a power amplifier configured to amplify the RF signal based on a supply voltage; and
an impedance modulation circuit coupled in series with the power amplifier and configured to modulate a load impedance at an output of the power amplifier to thereby reduce a voltage range of the supply voltage; and
a power management integrated circuit (PMIC) configured to:
generate the supply voltage based on the target voltage and provide the supply voltage to the power amplifier; and
generate and provide a load modulation signal to the impedance modulation circuit to indicate the load impedance at the output of the power amplifier when a power level of the RF signal is below a first power threshold and above a second power threshold lower than the first power threshold.

13. The wireless device of claim 12, wherein the impedance modulation circuit comprises:
a modulated impedance inverter configured by at least one configuration parameter to modulate the load impedance at the output of the power amplifier; and
a control circuit configured to receive the load modulation signal and determine the at least one configuration parameter based on the load impedance indicated by the load modulation signal.

14. The wireless device of claim 13, wherein the modulated impedance inverter comprises:
a pair of tunable capacitors coupled in series between an input node and an output node; and
an inductor coupled between a respective middle node located between the pair of tunable capacitors and a ground;
wherein the at least one configuration parameter comprises a respective capacitance of each of the pair of tunable capacitors.

15. The wireless device of claim 13, wherein the modulated impedance inverter comprises:
a pair of tunable capacitors coupled in series between an input node and an output node;
a pair of inductors coupled in series between a respective middle node located between the pair of tunable capacitors and a ground;
a second inductor coupled between the middle node and the ground in parallel to the pair of inductors; and
a second tunable capacitor coupled between a respective middle node located between the pair of inductors and the ground;
wherein the at least one configuration parameter comprises one or more of:
a respective capacitance of each of the pair of tunable capacitors; and
a respective capacitance of the second tunable capacitor.

16. The wireless device of claim 13, wherein the modulated impedance inverter comprises:
a pair of tunable capacitors coupled in series between an input node and an output node;
a pair of inductors coupled in series between a respective middle node located between the pair of tunable capacitors and a ground; and
a second tunable capacitor coupled between the respective middle node located between the pair of tunable capacitors and a respective middle node located between the pair of inductors;
wherein the at least one configuration parameter comprises one or more of:
a respective capacitance of each of the pair of tunable capacitors; and
a respective capacitance of the second tunable capacitor.

17. The wireless device of claim 13, wherein the modulated impedance inverter comprises:
a pair of first inductors coupled in series between an input node and an output node;
a pair of second inductors coupled in series between the input node and the output node in parallel to the pair of first inductors;
a tunable capacitor coupled between a respective middle node located between the pair of first inductors and a ground; and
a second tunable capacitor coupled between a respective middle node located between the pair of second inductors and the output node;
wherein the at least one configuration parameter comprises one or more of:
a respective capacitance of the tunable capacitor; and
a respective capacitance of the second tunable capacitor.

18. The wireless device of claim 13, wherein the modulated impedance inverter comprises:
a pair of inductors coupled in series between an input node and an output node; and
a tunable capacitor coupled between a respective middle node located between the pair of inductors and a ground;
wherein the at least one configuration parameter comprises a respective capacitance of the tunable capacitor.

19. The wireless device of claim 13, wherein the modulated impedance inverter comprises:
a pair of inductors coupled in series between an input node and an output node;
a pair of tunable capacitors coupled in series between a respective middle node located between the pair of inductors and a ground; and
a second inductor coupled between a respective middle node located between the pair of tunable capacitors and the ground;
wherein the at least one configuration parameter comprises a respective capacitance of each of the pair of tunable capacitors.

20. A method for supporting impedance modulation in a power management circuit comprising:
amplifying a radio frequency (RF) signal based on a supply voltage;
modulating a load impedance to thereby reduce a voltage range of the supply voltage; and
generating a load modulation signal indicating the load impedance when a power level of the RF signal is below a first power threshold and above a second power threshold lower than the first power threshold.
